(19) United States
(12) Patent Application Publication
(10) Pub. No.: US 2015/0340395 A1
(43) Pub. Date: Nov. 26, 2015

(54) PHOTODETECTOR ELEMENT FOR INFRARED LIGHT RADIATION, AND PHOTODETECTOR INCLUDING SUCH A PHOTODETECTOR ELEMENT

(71) Applicant: Commissariat à I'énergie atomique et aux énergies alternatives, Paris (FR)

(72) Inventors: Matthieu Duperron, Grenoble (FR); Roch Espiau de Lamaestre, Grenoble (FR); Olivier Gravrand, Fontanil Cornillon (FR)

(21) Appl. No.: 14/411,226

(22) PCT Filed: Jun. 19, 2013
(86) PCT No.: PCT/EP2013/062713

§ 371 Date: Dec. 24, 2014

(30) Foreign Application Priority Data
Jun. 26, 2012 (FR) 1256075

(51) Int. Cl. H01L 27/146

(52) U.S. Cl. CPC H01L 27/14625; H01L 27/14636

(57) ABSTRACT

A photodetector element for infrared light radiation of a given wavelength, in a medium that is at least partially transparent to the infrared light radiation to be detected. The photodetector includes a layer of a partially absorbent semiconductor and a periodic structure placed at a distance from and in the near field of the semiconductor layer and exciting propagation modes parallel to the semiconductor layer, of the infrared light radiation to be detected. There is a perimetric electrical contact that frames the outline of the photodetector element and extends perpendicularly relative to the planes defined by the semiconductor layer and the periodic structure, which makes contact with said semiconductor layer, and that also forms an optical mirror for the modes excited by the periodic structure.

### RELATED APPLICATIONS

This application is a U.S. National Stage of international application number PCT/EP2013/062713 filed Jun. 19, 2013, which claims the benefit of the priority date of French Patent Application FR 1256075, filed Jun. 26, 2012, the contents of which are herein incorporated by reference.

### FIELD OF INVENTION

The present invention relates to a photodetector element for infrared light radiation, in particular for photodetectors in the field of high quantum efficiency detectors, especially having a thin absorption layer.

### BACKGROUND

Quantum infrared photodetectors are already known. The latter must be cooled far below room temperature in order to minimize, even suppress, in the semiconductor, the process of thermal generation of carriers, or dark current, which competes with photogeneration of free carriers, or the useful signal.

To decrease this dark current, one alternative consists in decreasing the thickness of the semiconductor layer. In addition, this alternative may have other advantages such as for example increasing detection speed and decreasing manufacturing cost.

However, even though dark current is decreased, the quantum efficiency of the photodetector is also observed to decrease, which is undesirable given that this results in a decreased signal-to-noise ratio.

In order to mitigate this drawback, in the prior art a photon concentrating structure is associated with the photodetector, thereby allowing the loss of quantum efficiency to be at least partially compensated for and signal-to-noise ratio to be improved. These structures generally take the form of periodic structures that excite modes that propagate parallel to the absorbent semiconductor layer.

However, it has been observed that this measure is not always enough. Specifically, given that, in general, in a photodetector a plurality of photodetector elements are associated in the form of a matrix of pixels, the size of which must be as small as possible, within the diffraction limit of the optics placed in front of the photodetector, the extent of the periodic structure is limited and it loses its ability to couple the incident wave to the periodic structure.

In addition, to decrease the impact of the unacceptable increase in electrical access resistance, especially as regards pixels located at the center of the matrix, it becomes necessary to position electrical contacts serving to collect the freed charge in proximity to each pixel.

Photodetector elements implementing lateral collection of photogenerated charge are in particular known.

However, arranging such photodetector elements into a matrix involves a compromise between electrical and optical performance. From an electrical point of view, due to the thinness of the absorbent semiconductor layer, the access resistance of a pixel at the center of the matrix may become very high. It then becomes necessary to position two electrical contacts in proximity to each photodetector element. From an optical point of view, the finite size of the photodetector element imposes a finite number of periods on the coupling array. When this number of periods becomes too small, the incident light radiation and the absorbent layer are no longer coupled optimally by the array, and the quantum efficiency of the photodiode is observed to decrease.

In this case, a drop in quantum yield and a drop in signal-to-noise ratio are once more observed.

The following solutions have been advanced to address these problems:

Document WO 2005/081782 suggests using metal layers at the end of the coupling array. These vertical layers play the role of “mirrors” producing horizontal reflections and keeping the diffracted light in the pixel. However, the electrical contacts are formed above and below the absorbing layer (“vertical” electrical connection). Therefore, this arrangement does not allow the technical problem of access resistance in the contact configurations of interest here to be solved.

Document U.S. Pat. No. 6,133,571 relates to a photodetector with horizontal electrical contacts on opposite sides of an absorbent semiconductor structure. This photodetector furthermore provides vertical reflectors, for example made of gold, forming a cavity in order to obtain stationary electromagnetic waves in order to promote absorption in the absorbent layer. These reflectors are electrically insulated in all the embodiments by a perimetric insulating layer, for example made of SiO₂.

However, this solution is complex to obtain and does not solve the aforementioned problems.

### SUMMARY

The present invention aims to mitigate the aforementioned drawbacks at least in part.

For this purpose, the present invention provides a photodetector element for infrared light radiation of a given wavelength, comprising, in a medium that is at least partially transparent to the infrared light radiation to be detected:
a layer of a partially absorbent semiconductor; and
a periodic structure placed at distance from and in the near field of the semiconductor layer and exciting propagation modes, parallel to this semiconductor layer, of said infrared light radiation to be detected,
wherein it furthermore comprises a perimetric electrical contact that frames the outline of said photodetector element and extends perpendicularly relative to the planes defined by the semiconductor layer and said periodic structure, which makes contact with said semiconductor layer, and that also forms an optical mirror for the modes excited by said periodic structure.

It will therefore be understood that the perimetric electrical contact has a double function, namely an electrical function on the one hand and an optical function, as a reflector, on the other hand. The functionality of one of the electrical contacts required to collect charge has therefore been extended, thereby making it possible to improve the performance of a photodetector element having a simple structure.

In addition, by virtue of the optical cavity formed by the perimetric electrical contact, the coupling performance of the periodic structure is increased and the effect of the finite size of the periodic structure is considerably decreased. A high quantum yield is therefore preserved and signal-to-noise ratio may be improved.

In addition, the perimetric electrical contact allows, in a matrix structure of photodetector elements, the photodetector elements to be decoupled from one another, preventing optical or electrical cross-talk effects.

Lastly, there is less need to cool such a photodetector element, thereby making it much easier to use such a sensor.

The photodetector element may furthermore comprise the following features, whether alone or in combination:

According to one aspect, for the given wavelength to be detected, the distance between two opposite edges of the perimetric electrical contact is chosen in order to satisfy a resonance or quasi-resonance relationship taking into account the periodic structure arranged between said opposite edges of the perimetric electrical contact.

The distances between an edge of the perimetric electrical contact and the periodic structure may be chosen to satisfy the relationships:

$$\begin{matrix}{n}_{edge} {L}_{edge - 1} + {n}_{edge} {L}_{edge - 2} + {n}_{array} \cdot {L}_{array} = \frac{k \cdot {λ}_{0}}{2} & ( 1 ) \\ {n}_{edge} {L}_{edge - 1} = \frac{{k}_{1} {λ}_{0}}{2} & ( 2 \text{-} 1 ) \\ {n}_{edge} {L}_{edge - 2} = \frac{{k}_{2} {λ}_{0}}{2} & ( 2 \text{-} 2 )\end{matrix}$$

in the limit where:

$$- \frac{1}{8} \frac{{λ}_{0}}{{n}_{edges}} + \frac{{k}_{1 or 2} \cdot {λ}_{0}}{2 {n}_{edge}} \leq {L}_{edge - 1 or 2} \leq \frac{1}{8} \frac{{λ}_{0}}{{n}_{edges}} + \frac{{k}_{1 or 2} \cdot {λ}_{0}}{2 {n}_{edge}} \qquad ( 3 )$$

where:
λ₀ is the wavelength to be detected by the photodetector element;
L_{edge-1} and L_{edge-2} are the distances between the edge of the perimetric electrical contact (13) and the end subdivision (Me) of the periodic structure (9);
L_{array} is the length of the periodic structure;
n_{edge} is the effective index of the stack mode propagating in the zone comprised between the edge and the perimetric electrical contact;
n_{array} is the effective index of the mode propagating in the periodic structure, it may be defined by λ₀/P; and
k, k₁ and k₂ are integers.

According to another aspect, the thickness of the perimetric electrical contact is larger than the skin depth of the metal forming the perimetric contact.

The extension of the perimetric contact in a direction perpendicular to the plane defined by the periodic structure may be chosen in order to reflect at least 50% of the energy of the propagation modes of the periodic structure that are parallel to the semiconductor layer.

In addition, the inclination between the flank of the perimetric contact facing the periodic structure and a plane strictly perpendicular to the plane defined by the periodic structure is for example lower than 20°.

The photodetector element may furthermore comprise a layer forming a metal mirror arranged on the side opposite that on which the infrared radiation is incident, and the perimetric contact and the mirror layer are for example made of the same material.

According to one embodiment, the photodetector element is square in shape.

According to a variant, the periodic structure is a square array of square or circular features.

According to another embodiment, the periodic structure is a linear array.

According to yet another embodiment, the photodetector element is circular in shape and the perimetric electrical contact and the array are also circular.

Provision may be made for the partially absorbent semiconductor layer to take the form of a double layer formed by a layer of narrow bandgap HgCdTe facing the periodic structure and the edges of which are distant by at least 200 nm from the edges of the perimetric electrical contact, and a layer of wide bandgap HgCdTe making surface contact with the HgCdTe layer on the one hand and making electrical contact with the perimetric electrical contact on the other hand.

The invention also relates to a photodetector for infrared light radiation of at least one given wavelength, noteworthy in that it comprises a plurality of photodetector elements such as defined above.

This photodetector may comprise a plurality of photodetector elements configured to detect various given wavelengths.

According to one aspect, the photodetector comprises a matrix of photodetector elements the peripheral contacts of which are connected and at the same electrical potential.

Other features and advantages will become apparent on reading the description of the invention, and the following figures in which:

### BRIEF DESCRIPTION OF THE DRAWINGS

FIG. 1 schematically shows a top view of a portion of a photodetector, especially by way of example of polychromatic matrix of four photodetector elements;

FIG. 2 schematically shows in cross section one of the photodetector elements in FIG. 1;

FIG. 2A shows a cross-sectional view of a perimetric electrical contact having a slightly trapezoidal cross section;

FIG. 3 shows a stack of layers of a photodetector element in an enlargement II of FIG. 2;

FIG. 4 shows a variant of a stack of layers of a photodetector element;

FIGS. 5A and 5B show comparative results for a periodic structure according to the embodiment in FIG. 3;

FIGS. 6A to 6E schematically show one example process for manufacturing a photodetector element according to the invention;

FIG. 7 schematically shows a top view of another embodiment;

FIG. 8 schematically shows another top view of another embodiment;

FIG. 9 schematically shows yet another top view of another embodiment; and

FIG. 10 schematically shows a cross-sectional view of a variant of a photodetector element according to the invention.

### DETAILED DESCRIPTION

In all the figures, identical elements have been designated by the same reference numbers.

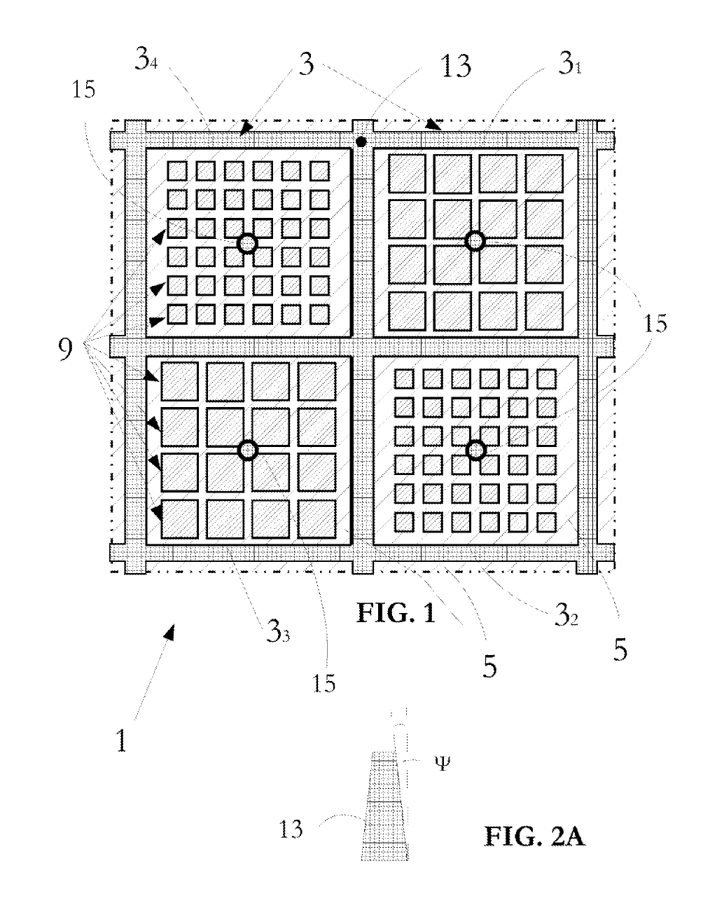

FIG. 1 shows an example embodiment of a photodetector 1 for detecting infrared light radiation of at least one given wavelength, in the present case two different wavelengths.

Specifically, this figure schematically shows a top view of a plurality of photodetector elements 3 or pixels, more particularly four photodetector elements 3₁, 3₂, 3₃ and 3₄. These four photodetector elements 3₁, 3₂, 3₃ and 3₄ may be said to form a superpixel.

According to the example shown here, the photodetector elements 3₁ and 3₃ and 3₂ and 3₄, respectively, are identical and dimensioned to detect the same wavelength.

Of course, all the photodetector elements 3 of the photodetector could be identical in order to detect just one wavelength, or indeed other photodetector elements 3 could be provided in order to detect more than two different wavelengths. A polychromatic photodetector may be obtained in this way.

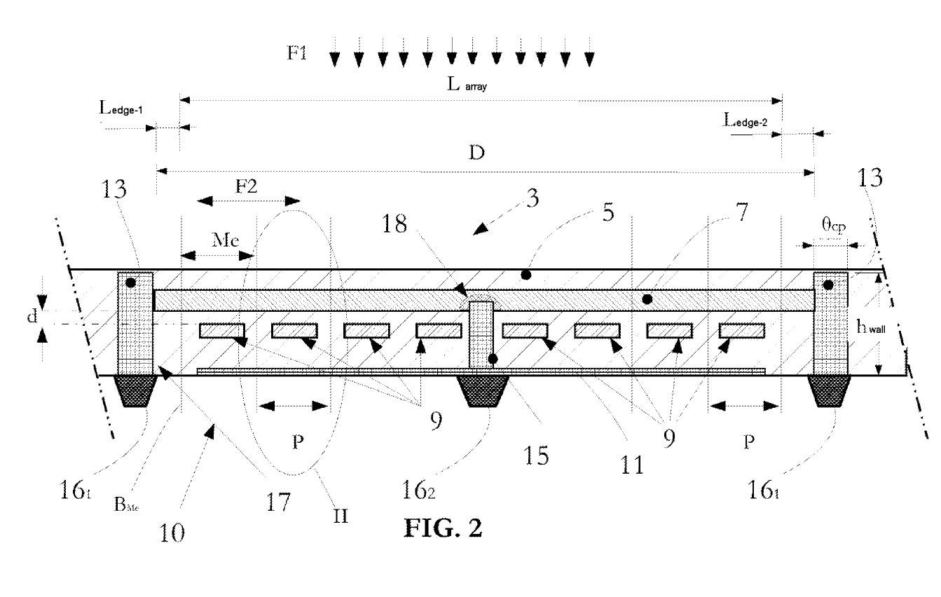

The photodetector elements 3 will now be described in more detail with regard to FIGS. 1 and 2.

Seen from above in FIG. 1, each photodetector element 3 comprises a substrate 5 that is a medium at least partially transparent to the infrared light radiation to be detected. This substrate is represented in FIG. 1 by large diagonal hatchings. It is for example a question of CdTe or CdZnTe. The substrate 5 may be formed from a layer made of a single material or of a stack of layers made of different materials.

With reference to FIG. 2, a layer 7 of a partially absorbent semiconductor is arranged in the substrate 5.

The semiconductor of the layer 7 and its thickness e are chosen so that at least 50% of the incident light radiation (indicated by the arrows F1 in FIG. 2) passes through this layer 7. This condition on the thickness may be formulated by the following equation:

$$e \leq 0.7 \times \frac{{λ}_{0}}{4 π \times {k}_{SC}}$$

where λ₀ is the wavelength to be detected by the photodetector element and k_{SC} is the imaginary part of the refractive index of the absorbent semiconductor.

The semiconductor will possibly be chosen from the following materials: Si, Ge, SiGe, InAs, InSb, GaSb, PbS, PbSe, PbTe or CdₓHg₁₋ₓTe (where x<0.9) (also called MCT for mercury cadmium telluride), ternary alloys such as InGaAs, AlInAs, AlInSb, InAsSb or InGaSb, quaternary alloys such as InGaAsP or InGaAsSb and quinternary alloys such as GalnAsSb or GalnAsSbP, or even a type-II superlattice, for example InAs/InSb on GaSb.

As shown in FIG. 2, below the absorbent layer 7 there is, arranged in the substrate, which may be a dielectric stack of layers made of different materials, a periodic structure 9 that is placed at distance from and in the near field of the semiconductor layer 7.

In FIG. 1, this periodic structure is represented by hatched squares 9, the size of the squares being different between the photodetector elements 3₁ and 3₃ on the one hand and 3₂ and 3₄ on the other hand in order to symbolize a different pitch P and therefore a different wavelength to be detected.

The function of this periodic structure 9 is to couple and concentrate the incident light on the semiconductor layer 7. More precisely, the periodic structure 9 makes it possible, by exciting propagation modes parallel to this absorbent semiconductor layer of said infrared light radiation to be detected, on the one hand to couple the incident light F1 in a direction (double arrow F2) parallel to the absorbent semiconductor layer 7, and on the other hand, to concentrate the electric field in the same layer 7. It therefore serves to improve the signal-to-noise ratio and allows the photodetector elements 3 to be spectrally differentiated (color sensors, spectroscopy, etc.).

The distance d between the periodic structure and the absorber layer 7 must be sufficiently small for this layer 7 to lie in the near field of the periodic structure 9.

This condition may be described by the following equation:

d≦λ₀/nₛ

where nₛ is the refractive index of the substrate 5.

The periodic structure 9 may take the form (as illustrated in FIG. 2) of a periodic network of metal features the pitch P of which especially allows the resonant wavelength of the periodic structure 9 to be adjusted.

According to one embodiment, especially for square photodetector elements, the periodic structure 9 is a square array of square features (see FIG. 1).

Variant periodic structures will be described below.

In addition, as may be seen in FIG. 2, on that face 10 of the photodetector element which is opposite the face receiving the incident light radiation is placed a reflective layer forming a mirror 11 (back mirror). It will be noted that this reflective layer 10, which forms a mirror, is optional in the context of the present invention, but its presence allows the performance of the photodetector elements to be significantly improved.

The collection of carriers is achieved by electrical contacts 13 and 15 connected by terminals 16₁ and 16₂, respectively, to processing electronics (not shown). In the context of the present invention the carriers are collected laterally, which is to say that, in the region of the absorbent semiconductor layer 7 where the electromagnetic field of the incident light is concentrated by the periodic structure 9, the lines of electrical equipotential are substantially perpendicular to the axis of the layer 7.

Thus, as may be seen in FIG. 2, the two electrical contacts 13 and 15 extend substantially perpendicularly to the planes defined by the semiconductor layer 7 and the periodic structure 9 and make contact with the absorbent semiconductor layer 7. In the context of the present invention, and as will be explained in more detail below, the term “perpendicular” is understood to mean a relative perpendicularity nonetheless ensuring a surface inclination lower than 20°.

The electrical contact 13 is a perimetric electrical contact (see FIG. 1) that frames the outline of the photodetector element 3.

As may be seen in FIG. 1, the perimetric electrical contact 13 frames the four photodetector elements 3 and is common to these elements. It is a question of the electrode or electrical contact forming the common electrical ground of the photodetector elements 3.

As is suggested in FIG. 1, the superpixel formed by the four photodetector elements may not be alone, but adjacent to other superpixels. In this case, the peripheral contact 13 is extended as shown in FIG. 1 and common to other superpixels.

Thus it is enough to connect the edges of the matrix formed by all the superpixels to connect electrically the contacts 13 of each photodetector element.

The electrical contacts 15 are for example arranged substantially in the center of each photodetector element 3 (or pixel) and are connected to processing electronics (not shown).

According to the example embodiment in FIG. 2, the central electrical contact 15 of the photodetector element 3 penetrates into the absorbent semiconductor layer 7.

According to one variant (not shown) the central electrical contact of each photodetector element 3 may be produced so as to completely pass through the absorbent semiconductor layer 7.

In addition, provision is made for a region 18 of doping in the absorbent semiconductor layer 7 around the central electrical contact 15 in order to form a collection diode.

These central electrical contacts 15 are specific to each photodetector element 3 and make it possible to collect independently the carriers photogenerated in each of the photodetector elements 3₁, 3₂, 3₃ defining the spatial resolution of the photodetector formed of a matrix of photodetector elements as shown in FIG. 1.

The electrical contacts 13 and 15 are made of a metal, for example a noble metal, such as gold or silver, or even of aluminum or copper, or indeed of an alloy of these various metals. Electrical contact metallizations such as described in the prior art, including Ti or Cr tie layers, satisfactorily perform the electrical contact function of the contact 15 and the double electrical contact and optical reflector function of the element 13.

According to the present example, the electrical contact 15 and the mirror layer 11 are made of the same material. The perimetric contact 13 may be made of the same material as that of the contact 15 and the layer 11.

Moreover, as is shown in FIG. 2, the mirror layer 11 makes contact with the central electrical contact 15 but is isolated from the perimetric electrical contact 13. According to an alternative (not shown) provision may be made for the mirror layer 11 to make contact with the perimetric electrical contact 13 but to be isolated from the central electrical contact 15.

It will be noted that the perimetric contacts 13 have, apart from their electrical function of transporting electrical charge, an optical function as they form, for each photodetector element 3, an optical mirror for the modes excited by the periodic structure 9.

More precisely, for the given wavelength to be detected λ₀, the distance D between two opposite edges of the perimetric electrical contact of a photodetector element 3 is chosen to satisfy a resonance or quasi-resonance relationship taking into account the periodic structure 9 arranged between these opposite edges of the perimetric electrical contact 13.

It will be noted that the central electrical contacts 15 have almost no affect on the modes excited by the periodic structure 9, and their influence on the propagation of the light radiation to be detected in a direction parallel to the absorbent semiconductor layer 7 may be neglected. The resonance or quasi-resonance relationship may also be expressed by the fact that the distances L_{edge-1} and L_{edge-2} between the edges of the perimetric electrical contact and the periodic structures satisfy the relationships:

$$\begin{matrix}{n}_{edge} {L}_{edge - 1} + {n}_{edge} {L}_{edge - 2} + {n}_{array} \cdot {L}_{array} = \frac{k \cdot {λ}_{0}}{2} cavity relationship & ( 1 ) \\ {n}_{edge} {L}_{edge - 1} = \frac{{k}_{1} {λ}_{0}}{2} phase relationship & ( 2 \text{-} 1 ) \\ {n}_{edge} {L}_{edge - 2} = \frac{{k}_{2} {λ}_{0}}{2} phase relationship & ( 2 \text{-} 2 )\end{matrix}$$

in the limit where:

$$- \frac{1}{8} \frac{{λ}_{0}}{{n}_{edges}} + \frac{{k}_{1 or 2} \cdot {λ}_{0}}{2 {n}_{edge}} \leq {L}_{edge - 1 or 2} \leq \frac{1}{8} \frac{{λ}_{0}}{{n}_{edges}} + \frac{{k}_{1 or 2} \cdot {λ}_{0}}{2 {n}_{edge}} \qquad ( 3 )$$

where:
λ₀ is the wavelength to be detected by the photodetector element;
L_{edge-1} and L_{edge-2} (see FIG. 2) are the distances between the edge of the perimetric electrical contact 13 and the end subdivision (Me) of the periodic structure (9), i.e. the distance between the subdivision containing an end feature of the periodic structure 9 and an adjacent edge. At the edge B_{Me} of the end subdivision Me the electrical field is zero for the horizontal propagation mode in question at the wavelength λ₀. In FIG. 2, L_{edge-1} and L_{edge-2} are identical (L_{edge-1}=L_{edge-2}=L_{edge}) but in other embodiments they may have different values;
L_{array} is the length of the periodic structure (see FIG. 2);
n_{edge} is the effective index of the stack mode propagating in the zone comprised between the edge and the perimetric electrical contact;
n_{array} is the effective index of the mode propagating in the periodic structure, it may be defined by λ₀/P; and
k, k₁ and k₂ are integers.

The above definitions are especially applicable to two-dimensional periodic structures, but may be applied without difficulty to more complex periodic structures, three-dimensional structures for example.

Specifically, it has been observed that the distance L_{edge}, and therefore the arrangement of the perimetric electrical contact 13 relative to the periodic structure 9, affects whether destructive or constructive interference occurs, which influences the absorption performance of the photodetector elements 3. The aim of the above conditions is therefore to maximize the absorption of the photodetector elements 3 by ensuring L_{edge} is set so that constructive interference is more likely to occur.

Furthermore, the thickness θ_{cp} of the perimetric electrical contact 13 is larger than the skin depth of the metal forming the perimetric contact, which is to say that θ_{cp}≧δ(λ₀). This makes it possible to decrease, even suppress, any transmission of a mode excited by the periodic structure 9 parallel to the plane defined by the absorbent semiconductor layer 7 and to prevent problems with cross-talk between photodetector elements 3 of a matrix of photodetectors.

In addition, the extension h_{wall} of the perimetric contact in a direction perpendicular to the plane defined by the periodic structure 9 is chosen to reflect at least 50% of the energy of the propagation modes of the periodic structure that propagate parallel to the semiconductor layer 7.

This relationship may be described by the following relationship:

∫₀^{hwall}∈(z)|E_{mode}(z)|²dz≧0.5∫₀^{∞}∈(z)|E_{mode}(z)|²dz

where ∈(z) is the dielectric constant of the layers of the photodetector element 3 in the direction z parallel to the extension of the perimetric contact.

Another parameter to be taken into consideration is the inclination between the flank 17 of the perimetric contact 13 facing the periodic structure 9 and a plane strictly perpendicular to the plane defined by the periodic structure 9. This angle of inclination ψ is chosen to be lower than 20° [in FIG. 2 it is 0° ].

FIG. 2A illustrates, by way of example, a perimetric electrical contact 13 the flank of which is inclined at an angle ψ and which therefore would not be strictly perpendicular to the plane defined by the periodic structure 9.

It will therefore be understood that a photodetector element 3 is a stack of various layers bordered by a peripheral contact 13 inside and between which a repetitive array of features of pitch P is placed in order to form the periodic structure.

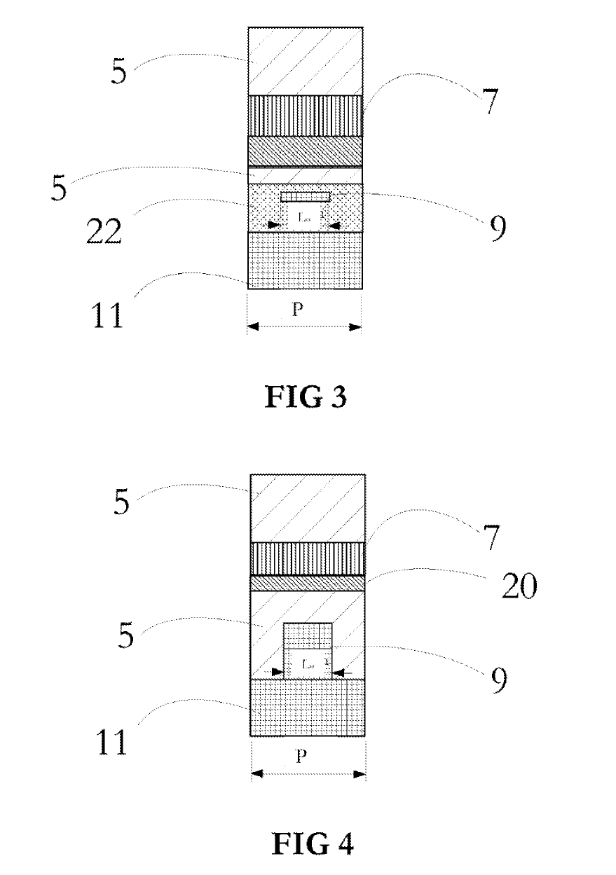

Reference is now made to FIG. 3 which shows in cross section, in greater detail than in FIG. 2, the stack of the various layers.

In FIG. 3, from top to bottom, i.e. in the direction of the incident light radiation, there is first a first substrate layer 5 and then the absorbent semiconductor layer 7, which is, for example, made of MCT that is, for example, about 400 nm thick.

Below the layer 7 a, for example about 400 nm thick, bandgap widening layer (for example made of Hg₁₋ₓCdₓTe where x is variable) is arranged in order to passivate the absorbent semiconductor layer.

Next, there follows a substrate layer 5 made of CdTe that is about 100 nm thick, followed by a layer 22 of ZnS that is about 500 nm thick and that encloses the periodic structure 9, which is about 50 nm thick and about 50 nm from the substrate layer 5 contiguous to the ZnS layer 22. The array is formed in the present case by square metal plates that are, for example, made of gold. Lastly, a mirror layer 11, for example also made of gold, is formed below the layer 22.

The refractive indices of the materials in the 3-5 μm range studied here are:
n(CdTe)=2.67
n(GWL)=3.03
n(ZnS)=2.25
n(MCT)=3.4+i×(−5.0e4×λ₀+0.454)
n(Au) corresponds to that described and established by Palik.

The period P of the periodic array is set to 1.5 μm in order to obtain a photodetector element 3 resonant at 4.3 μm. The size L_{M} of the square metal plate is 0.5×1.5 μm=750 nm.

An alternative periodic structure 9 is shown in FIG. 4.

Whereas the periodic structure 9 in FIGS. 2 and 3 is formed of metal plates enclosed in a ZnS layer and distant from the mirror layer 11, the periodic structure in FIG. 4 is a structured metal mirror formed of portions recessed and raised in alternation with a preset pitch that allows the wavelength of the infrared light radiation to be detected to be adjusted.

In greater detail, in FIG. 4, from top to bottom, i.e. in the direction of the incident light radiation, there is first a first substrate layer 5 and then the absorbent semiconductor layer 7, which is, for example, made of MCT that is, for example, about 200 nm thick.

Below the layer 7 a, for example about 100 nm thick, bandgap widening layer (for example made of Hg₁₋ₓCdₓTe where x is variable) is arranged in order to passivate the absorbent semiconductor layer.

Next, there follows a substrate layer 5 made of CdTe that is about 900 nm thick, into which the periodic structure 9 protrudes the latter taking the form of pads that are, for example, made of 600 nm-thick gold and that are about 300 nm distant from the gap widening layer 20 contiguous to the substrate layer 5. Lastly, a mirror layer 11, for example also made of gold, is arranged below the substrate 5. Regarding the structured mirror, a waffle structure is also spoken of.

The refractive indices of the materials in the 3-5 μm range studied are the same as those indicated for FIG. 3.

The period P of the array is 1.59 μm in order to obtain a resonance at 4.3 μm. The size L_{M} of the pad is for example 0.4×1.59 μm=636 nm.

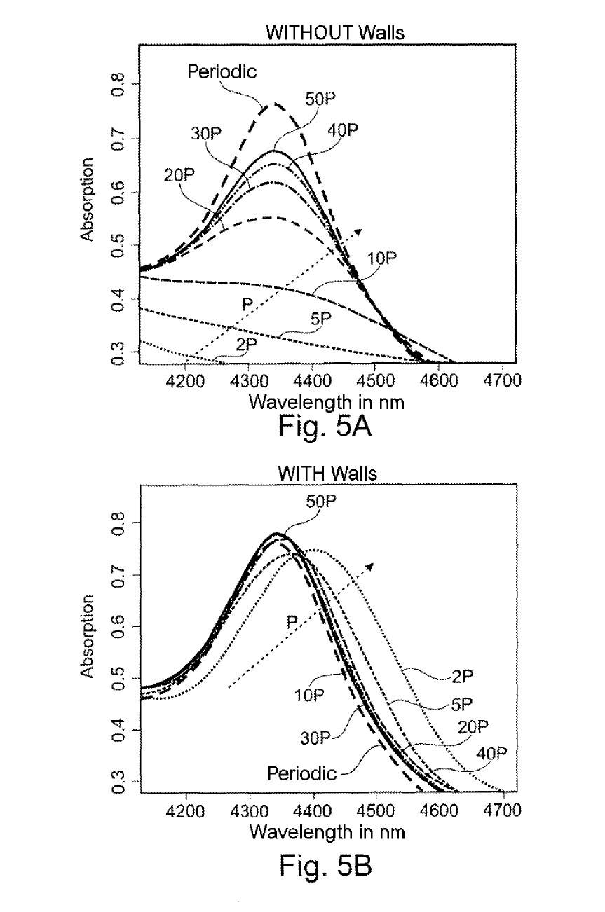

FIGS. 5A and 5B present the results of a numerical simulation showing the advantage provided by perimetric electrical contacts 13 having both an electrical and optical function.

FIG. 5A shows the absorption response of a photodetector element having a stack structure according to FIG. 3, but without a perimetric electrical contact. To obtain the various curves, the number of periods P contained in a single photodetector element was varied (P increases in the direction of the arrow on the graph). The dotted curve shows the response of an ideal infinite array.

It may be seen that photodetector elements 3 having only one periodic structure 9 with a small number of periods are inefficient and that it is only with more than 50 periods that an efficiency of about 90% of an infinite periodic structure is barely obtained.

FIG. 5B presents the same results for a photodetector element 3 such as shown in FIGS. 1 to 3, i.e. one comprising perimetric electrical contacts 13.

In this case, even with a very small number of periods, indeed even with only two periods, an efficiency already corresponding to 90% of the efficiency of an ideal infinite periodic structure is achieved.

How to obtain a good efficiency despite a low number of periods is one problem faced when designing matrices of pixels. For example, if it is desired to use pixels of 15 μm×15 μm, with the existing prior-art solution, i.e. without perimetric electrical contacts also acting as mirrors, if an array of 1.5 μm periodicity resonant in the 3-5 μm band is used only 10 periods may be arranged in one photodetector element. The excitation of the resonance will therefore be very weak (a few percent of the infinite periodic resonance). For a comparable geometric size, with the perimetric contact having both optical and electrical functions only 9 array periods are obtained, but the response allows an efficiency that is fairly close to that of an ideal infinite periodic structure to be achieved.

In addition, by completely separating the photodetector elements, any form of cross-talk is prevented. Electrical cross-talk due to carriers generated in one pixel but collected in another becomes impossible because of the presence of the perimetric electrical contact. Optical cross-talk due to the extension of one optical mode from one pixel into another pixel can no longer exist because the modes are refracted by the metal flanks, this is particularly necessary in the context of a matrix of polychromatic photodetector elements.

Comparable but slightly less marked results were obtained in terms of performance for a periodic structure taking the form of a structured mirror according to FIG. 4.

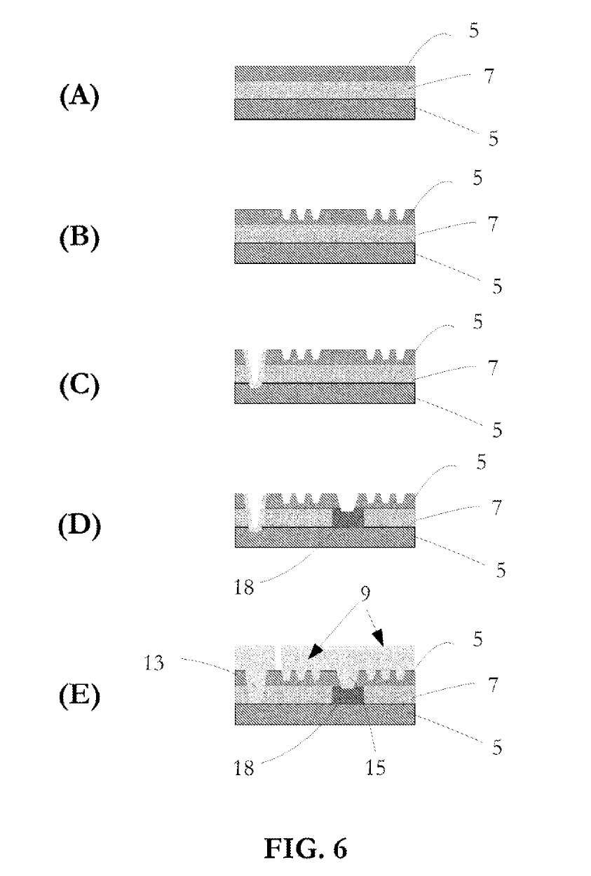

FIGS. 6A to 6E show simplified schematics illustrating an example process for manufacturing a photodetector element according to the invention, in relation to the embodiment in FIG. 4.

In a first step, the surface of the, for example CdTe, substrate 5 is prepared and a layer of MCT and then a passivation layer, for example also made of CdTe, are deposited on the substrate 5 by molecular beam epitaxy (see FIG. 6A).

Next, by lithography and etching, holes are created by removing material in order to form the features of the periodic structure 9 (see FIG. 6B).

Next, holes are produced in order to form the perimetric contacts 13 (see FIG. 6C).

As may be seen in FIG. 6D, a discrete hole is produced for the central contact 15 with doping inversion during etching in order to allow the collection diode to be formed.

Lastly, as shown in FIG. 6E, a metallization is carried out for final production of the perimetric contacts 13, central contacts 15 and the back mirror 11.

Of course, other production processes may be envisioned without departing from the scope of the present invention.

Relative to the embodiments in FIGS. 1 to 4, multiple variants are envisionable without departing from the scope of the present invention.

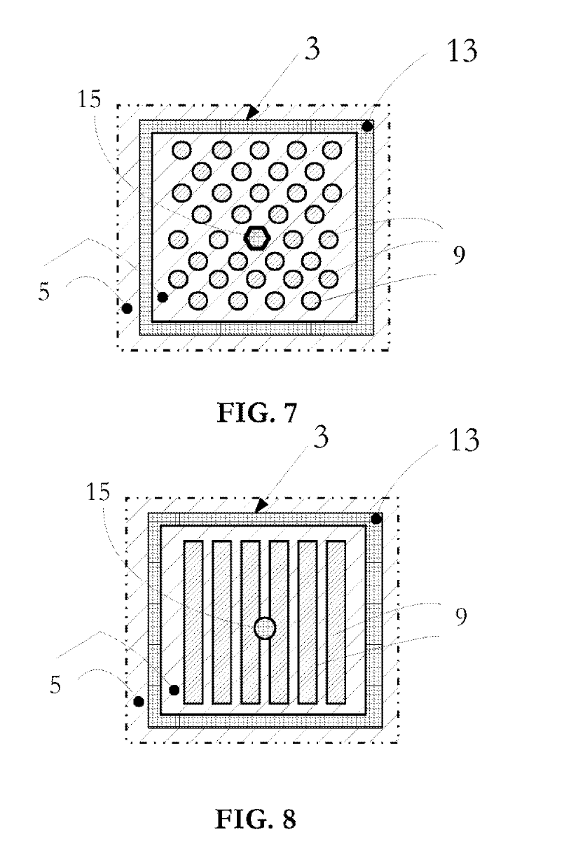

Thus, FIG. 7 shows a square photodetector element 3 but with a hexagonal periodic structure.

FIG. 8 shows a variant that differs from the variant in FIG. 1 in that the periodic structure 9 is a linear array, thereby in addition making it possible to determine the polarization of the incident infrared light radiation. Thus, for example by arranging arrays of two photodetector elements adjacent and perpendicular to one another, light radiation may in addition be detected as a function of polarization.

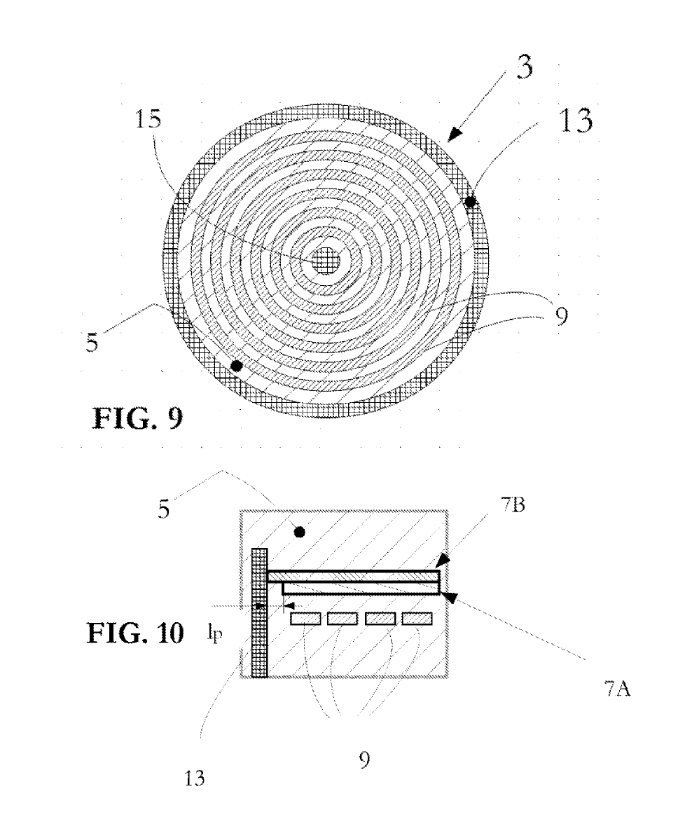

According to another variant shown in FIG. 9, the photodetector element 3 is circular, the perimetric electrical contact 13, the periodic structure 9 and the array are circular and the electrical contact 15 takes the form of a central pad.

According to yet another variant, the partially absorbent semiconductor layer 7 takes the form of a double layer 7A and 7B formed by a layer 7A of narrow bandgap HgCdTe facing the periodic structure 9 and the edges of which are distant by a passivation distance Iₚ of at least 200 nm from the edges of the perimetric electrical contact 13, and a layer 7B of wide bandgap HgCdTe, of thickness larger than 100 nm, making surface contact with the HgCdTe layer 7A on the one hand and making electrical contact with the perimetric electrical contact on the other hand. The advantage of this configuration is that it decreases the contribution of the perimetric electrical contacts 13 to the total detection noise because the contacts 13 are connected to a wider bandgap semiconductor.

This type of infrared photodetector has applications in a very large number of both civil and military fields. Regarding the latter, mention may be made of seekers (for which the filtering function is a critical counter countermeasure) or of (compact and low cost) on-board sensors for drones and of light equipment for infantry. In the civil field, applications are very diverse and may relate to the protection of property or people (surveillance, thermal cameras for firefighting and night-time driving obstacle avoidance); to the detection of leaks and nondestructive testing in industrial installations (fluid transport or electrical transmission, aerial and rail transportation); to environmental monitoring (satellite imagery; building energy performance assessment); and lastly to medical diagnosis (inflammations).

It should be understood therefore that the size of the photodetector elements described above may be decreased while preserving a high quantum efficiency and signal-to-noise ratio while minimizing even suppressing problems with cross-talk.

In addition, it will be noted that the decreased dark noise makes it possible optionally to increase the operating temperature of these detectors, and therefore to decrease the cost of the corresponding cryogenic system.

It is also possible to increase the detection speed passband because of the small size of the photodetectors.

Lastly, it is optionally possible to make the photodetector sensitive to the polarization of the incident light using a linear configuration instead of pads.

1-15. (canceled)

16. A photodetector element for infrared light radiation of a given wavelength, comprising, in a medium that is at least partially transparent to the infrared light radiation to be detected:
a layer of a partially absorbent semiconductor; and
a periodic structure placed at distance from and in the near field of the semiconductor layer and exciting propagation modes, parallel to this semiconductor layer, of said infrared light radiation to be detected, wherein it furthermore comprises a perimetric electrical contact that frames the outline of said photodetector element and extends perpendicularly relative to the planes defined by the semiconductor layer and said periodic structure, which makes contact with said semiconductor layer, and that also forms an optical mirror for the modes excited by said periodic structure.

17. The photodetector element as claimed in claim 16, wherein, for the given wavelength to be detected, the distance between two opposite edges of the perimetric electrical contact is chosen in order to satisfy a resonance or quasi-resonance relationship taking into account the periodic structure arranged between said opposite edges of the perimetric electrical contact.

18. The photodetector element as claimed in claim 16, wherein the distances between an edge of the perimetric electrical contact and the periodic structure satisfy the relationships:
$$\begin{matrix}{n}_{edge} {L}_{edge - 1} + {n}_{edge} {L}_{edge - 2} + {n}_{array} \cdot {L}_{array} = \frac{k \cdot {λ}_{0}}{2} & ( 1 ) \\ {n}_{edge} {L}_{edge - 1} = \frac{{k}_{1} {λ}_{0}}{2} & ( 2 \text{-} 1 ) \\ {n}_{edge} {L}_{edge - 2} = \frac{{k}_{2} {λ}_{0}}{2} & ( 2 \text{-} 2 )\end{matrix}$$
in the limit where:
$$- \frac{1}{8} \frac{{λ}_{0}}{{n}_{edges}} + \frac{{k}_{1 or 2} \cdot {λ}_{0}}{2 {n}_{edge}} \leq {L}_{edge - 1 or 2} \leq \frac{1}{8} \frac{{λ}_{0}}{{n}_{edges}} + \frac{{k}_{1 or 2} \cdot {λ}_{0}}{2 {n}_{edge}} \qquad ( 3 )$$
where:
λ₀ is the wavelength to be detected by the photodetector element;
L_{edge-1} and L_{edge-2} are the distances between the edge of the perimetric electrical contact and the end subdivision of the periodic structure;
L_{array} is the length of the periodic structure;
n_{edge} is the effective index of the stack mode propagating in the zone comprised between the edge and the perimetric electrical contact;
n_{array} is the effective index of the mode propagating in the periodic structure, it may be defined by λ₀/P; and
k, k₁ and k₂ are integers.

19. The photodetector element as claimed in claim 16, wherein the thickness of the perimetric electrical contact is larger than the skin depth of the metal forming the perimetric contact.

20. The photodetector element as claimed in claim 16, wherein the extension of the perimetric contact in a direction perpendicular to the plane defined by the periodic structure is chosen to reflect at least 50% of the energy of the propagation modes of the periodic structure that are parallel to the semiconductor layer.

21. The photodetector element as claimed in claim 16, wherein the inclination between the flank of the perimetric contact facing the periodic structure and a plane strictly perpendicular to the plane defined by the periodic structure is lower than 20°.

22. The photodetector element as claimed in claim 16, furthermore comprising a layer forming a metal mirror arranged on the side opposite that on which the infrared radiation is incident, wherein the perimetric contact and the mirror layer are made of the same material.

23. The photodetector element as claimed in claim 16, wherein it is square in shape.

24. The photodetector element as claimed in claim 16, wherein the periodic structure is a square array of square or circular features.

25. The photodetector element as claimed in claim 16, wherein the periodic structure is a linear array.

26. The photodetector element as claimed in claim 16, wherein it is circular in shape and in that the perimetric electrical contact and the array are also circular.

27. The photodetector element as claimed in claim 16, wherein the partially absorbent semiconductor layer takes the form of a double layer formed by a layer of narrow bandgap HgCdTe facing the periodic structure and the edges of which are distant by at least 200 nm from the edges of the perimetric electrical contact, and a layer of wide bandgap HgCdTe making surface contact with the HgCdTe layer on the one hand and making electrical contact with the perimetric electrical contact on the other hand.

28. A photodetector for infrared light radiation of at least one given wavelength, wherein it comprises a plurality of photodetector elements for infrared light radiation of a given wavelength, comprising, in a medium that is at least partially transparent to the infrared light radiation to be detected:
a layer of a partially absorbent semiconductor; and
a periodic structure placed at distance from and in the near field of the semiconductor layer and exciting propagation modes, parallel to this semiconductor layer, of said infrared light radiation to be detected,
wherein it furthermore comprises a perimetric electrical contact that frames the outline of said photodetector element and extends perpendicularly relative to the planes defined by the semiconductor layer and said periodic structure, which makes contact with said semiconductor layer, and that also forms an optical mirror for the modes excited by said periodic structure.

29. The photodetector as claimed in claim 28, wherein it comprises a plurality of photodetector elements configured to detect various given wavelengths.

30. The photodetector as claimed in claim 28, wherein it comprises a matrix of photodetector elements the peripheral contacts of which are connected and at the same electrical potential.
